(19) United States
(12) Patent Application Publication
(10) Pub. No.: US 2005/0068842 A1
(43) Pub. Date: Mar. 31, 2005

(54) Electronic device, nonvolatile memory and method of overwriting data in nonvolatile memory

(75) Inventor: Kenichiro Tominaga, Kanagawa (JP)

Correspondence Address: MCGINN & GIBB, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 10/949,666

(22) Filed: Sep. 27, 2004

(30) Foreign Application Priority Data
Sep. 29, 2003 (JP) 2003-336646

(51) Int. Cl. G11C 8/02

(52) U.S. Cl. 365/232

(57) ABSTRACT

An electronic device comprises a first and a second nonvolatile memory areas respectively having a data area for storing data and an identifying information area for storing identifying information which indicates whether the data is valid or invalid, and an overwrite portion for overwriting data to the first and second memory areas, wherein the overwrite portion writes new data to the data area of the second memory area if old data is stored in the data area of the first memory area, and writes the identifying information to the identifying information area of the first or second memory area, the identifying information indicating that the data area of the second memory area is valid.

### BACKGROND OF THE INVENTION

1. Field of the Invention

This invention relates to electronic devices, nonvolatile memories and methods of overwriting data in the nonvolatile memory which prevent damaged data caused by a power interruption.

2. Description of Related Art

In nonvolatile memories, flash memories that are erasable and writable per sector are used for storing BIOS (Basic Input/Output System) for PCs (personal computers) and used in, for example, memory cards for digital cameras, home-use game machines and the like.

Also, the microprocessors which incorporate the flash memory have been developed. This allows the overwriting of the program even if the microprocessor is mounted state on the circuit board. Further, this allows the self-programming that the program overwrites itself while the program in the microprocessor is running.

For example, in the case where the system failure is caused by the power interruption that occurred when overwriting data (including erasing and writing data) in the flash memory, the data being overwritten may be damaged. If the important data of the system is damaged, the system does not reboot successfully.

In order to prevent such damaged data due to the power interruption, the method of overwriting data shown in FIGS. 7A to 7E has been employed. In this method, as shown in the figure, nonvolatile areas 70, 71 and 72 which are the sectors of the flash memory are used. While the size of the nonvolatile areas 70 and 71 are the same to each other, the size of the nonvolatile area 72 may be different from other areas.

First, old data having been written as “DATA” is stored in the nonvolatile area 70 (FIG. 7A). At this time, no data is stored in the nonvolatile area 72, so that the CPU is, for example, operated under the condition that the nonvolatile area 70 is a valid area. Next, when overwriting data, the data is copied from the nonvolatile area 70 to the nonvolatile area 71 (FIG. 7B). Then, the information indicative of the validness of the nonvolatile area 71 is written to the nonvolatile area 72 (FIG. 7C). While this information is being stored in the nonvolatile area 72, the CPU is operated under the condition that the nonvolatile area 71 is a valid area. After that, new data “DATA′” is written to the nonvolatile area 70 (FIG. 7D). Generally, in flash memories, erasing of data is necessary prior to writing of data. Finally, upon proper completion of overwriting data, the data of the nonvolatile area 72 is erased, then the data of the nonvolatile area 71 is erased, and the overwriting operation is completed (FIG. 7E). In this process, the CPU is operated under the condition that the nonvolatile area 70 is a valid area as well as FIG. 7A.

For example, when the system reboots after power interruption that occurred when overwriting data to the nonvolatile area 70 at the state of FIG. 7D, nonvolatile area 72 is referred to and, by using the nonvolatile area 71 which stores the proper data, the CPU can be operated under the state before the overwriting was performed.

In this method, however, three nonvolatile areas which are independently erasable are needed, causing poor memory use efficiency. Further, the problem of slow overwriting operation arises because the new data is written after the old data is once copied.

Japanese Unexamined Patent Application Publication No. H9-34807 discloses a conventional method of overwriting data in a nonvolatile memory. In addition, a method of detecting an error of written data by checksum is known (see Japanese Unexamined Patent Application Publication No. 2003-157204), and a method of using status information of overwriting operation is also known (see Japanese Unexamined Patent Application Publication No. 2003-36209).

As described above, in the conventional method of overwriting data in the nonvolatile memory, in order to prevent damaged data caused by the power interruption, three nonvolatile areas which are independently erasable are required, causing poor memory use efficiency, and the problem of slow overwriting operation arises because the new data is written after the old data is once copied.

### SUMMARY OF THE INVENTION

This invention is to solve the problems above, that is, to provide electronic devices, nonvolatile memories and methods of overwriting data in the nonvolatile memory which can improve the memory use efficiency with protecting the data corruption due to the power interruption, and further to provide faster overwriting operation.

An electronic device comprises a first and a second nonvolatile memory areas respectively having a data area for storing data and an identifying information area for storing identifying information which indicates whether the data is valid or invalid, and an overwrite portion for overwriting data to the first and second memory areas, wherein the overwrite portion writes new data to the data area of the second memory area if old data is stored in the data area of the first memory area, and writes the identifying information to the identifying information area of the first or second memory area, the identifying information indicating that the data area of the second memory area is valid.

According to other aspect, a nonvolatile memory comprises a first memory area a second memory area. The first memory area has a first data area for storing data and a first identifying information area for storing identifying information which indicates whether the data is valid or invalid. The second memory area has a second data area if old data is stored in the first data area, the second identifying information area for storing identifying information which indicates whether the data is valid or invalid. An identifying information is written to the first or second identifying information area, the identifying information indicating that the data area of the second memory area is valid.

A method of overwriting data in a nonvolatile memory comprises writing new data to a data area of a second nonvolatile memory area if old data is stored in a data area of a first nonvolatile memory area, and writing identifying information into a identifying information area of the first or second memory area, the identifying information indicating that the second memory area is valid.

In this invention, the old data and the new data may be protection information which indicates an enable or a disable of overwriting in a third nonvolatile memory area, and the first and the second memory areas may be sectors of a flash memory. The electronic device according to the present invention is able to prevent damaged data due to the power interruption by using only two memory areas, which allows higher memory use efficiency. Further, since there is no process of copying the old data, faster overwriting operation is achieved. In addition, damaged data on the protection information is prevented, allowing the improved reliability. Moreover, the memory areas are erased in one operation, providing faster overwriting operation.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 shows a block diagram of the microprocessor according to the present invention.

FIGS. 2A and 2B show block diagrams of the flash memory according to the present invention.

FIG. 3 shows a block diagram of the flash memory control circuit according to the present invention.

FIG. 4 shows a flow chart of a method of overwriting data according to the present invention.

FIGS. 5A to 5D show state diagrams of the method of overwriting data according to the present invention.

FIGS. 6A to 6D show state diagrams of the method of overwriting data according to the present invention.

FIGS. 7A to 7E show state diagrams of the prior art method of overwriting data.

### DESCRIPTION OF THE PREFERRED EMBODIMENTS

First Embodiment

First, a structure of the microprocessor according to the first embodiment of the invention is explained with reference to FIG. 1. As shown in FIG. 1, the microprocessor 10 comprises a CPU 11, a RAM 12, a ROM 13, a flash memory 14 and a flash memory control circuit 15 (overwriting portion). The microprocessor 10 may additionally include input and output terminals. The CPU 11 is connected to the RAM 12, the ROM 13, the flash memory 14 and the flash memory control circuit 15 via buses or the like. The flash memory control circuit 15 is also connected to the flash memory 14.

The microprocessor 10 can be any microprocessor comprising the components shown in the figures, for example, an MPU (Micro Processing Unit), an MCU (Micro Controller Unit), or an ASIC (Application Specific Integrated Circuit). Also, the microprocessor 10 can be a one-chip microprocessor, or can be divided into a plurality of chips and connected therewith.

The microprocessor 10 operates based on a user program or a boot program. The user program or the boot program is designed by a user, and written in the flash memory 14 of the microprocessor 10.

The CPU 11 is a central processing unit. For example, the CPU 11 reads out the commands in the program from the ROM 13 and the flash memory 14, reads or writes data to the RAM 12 or the flash memory 14 according to the commands, and carries out the various operations.

The RAM 12 is a volatile memory, e.g., a DRAM (Dynamic RAM) or an SRAM (Static RAM). The RAM 12 is, for example, used for temporarily reading or writing data of the CPU 11 as a main memory or a cash memory.

The ROM 13 is a nonvolatile memory, which can be, for example, a non-rewritable mask ROM, a rewritable EPROM (Erasable Programmable ROM), an EEPROM (Electrically Erasable Programmable ROM), or a flash memory. The ROM 13 stores, for example, a base program. The base program is a fundamental program for the operation of the microprocessor 10, and cannot be modified. The base program includes, for example, commands to overwrite data of the flash memory 14.

The flash memory 14 is a nonvolatile memory in which data can be erased and written per sector. The flash memory 14 stores, for example, a user program or a boot program. The user program is a program describing desired operations for the user, and it is operated according to the base program mentioned above. The boot program is a program to start the microprocessor. The boot program describes the initial values and operations necessary during startup. Otherwise, the flash memory 14 can also store the base program instead of the ROM 13. The structure of the flash memory 14 is described later.

Some programs such as the user program are written to the flash memory 14 by using the program to overwrite data included in the base program. The flash memory 14 can be overwritten by the user program and the program for overwriting data. It is called self-programming that the user program itself is overwritten during the program running. For example, the self-programming is carried out by saving an overwriting portion of the user program on the RAM 12 and then overwriting the user program remaining in the flash memory 14. The programming can also be carried out by connecting a writer that is a write-only device to the microprocessor 10 and using the base program.

The flash memory control circuit 15 is a circuit for overwrite control of the data in the flash memory 14. The overwrite control includes, generating an address for new data, generating new data, generating a mode signal indicating a writing mode or an erasing mode, generating a clock for the overwriting, controlling a security flag explained later, and so on. The flash memory control circuit 15 is designed as, for example, a macro cell of one function block, and placed and wired in the most suitable place in the microprocessor 10. The configuration and operation of the flash memory control circuit 15 are explained later.

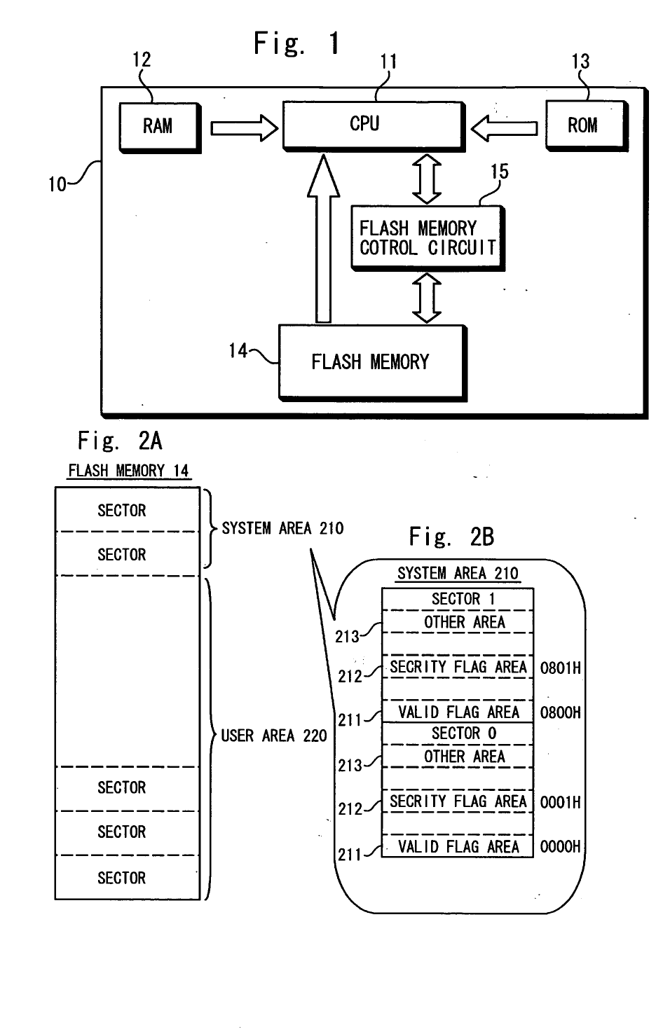

Next, the configuration of the flash memory 14 according to this embodiment is explained below with reference to FIGS. 2A and 2B. The flash memory 14 comprises a system area 210 and a user area 220 as shown in FIG. 2A.

The system area 210 and the user area 220 comprise a plurality of sectors as shown in the figure. A sector is the smallest unit to erase, and the erasing of data is performed per sector. The data can be written per sector or byte which is smaller than a sector. It is also possible to write data per block which includes a plurality of the sectors. Further, in a structure with a plurality of flash memories, each of the areas or sectors can be included in the different flash memories 14.

The user area 220 has any number of sectors as shown in FIG. 2A. The user area 220 stores the user program and the boot program mentioned above. A portion of the user area 220 can also be used to store the boot program only.

The system area 210 comprises two sectors of a sector 0 and a sector 1 as shown in FIG. 2B. Each of the sectors 0 and 1 further comprises a valid flag area 211, a security flag area 212, and the other area 213. For example, the valid flag area 211 of the sector 0 is assigned to the address 0000H, so are the security flag area 212 of sector 0 to 0001H, the valid flag area 211 of the sector 1 to 0800H, and the security flag area 212 of the sector 1 to 0801H. Here, one sector has 2K bytes. In addition, 1K byte is equal to 1024 bytes and the suffix “H” represents a hexadecimal form.

The valid flag area 211 stores a valid flag. This valid flag is a flag for indicating whether the sector 0 or 1 is valid or invalid. By this valid flag, a valid sector is singled out from the sectors 0 and 1. In the valid sector, the data of the security flag area 212 and the other area 213 become valid. The value can also be stored in one of the valid areas of the sectors 0 and 1. The valid flag control is explained later.

One of the sectors 0 and 1 that is determined as valid by the valid flag is hereafter referred to as the valid sector. One of the sectors 0 and 1 that is determined as invalid by the valid flag is referred to as the invalid sector.

The security flag area 212 stores a security flag. This security flag is a flag for the overwrite protection which enables or disables the user area 220 to be overwritten. The security flag includes, for example, a flag to disable the writing in the user area 220, a flag to erase the sector in the user area 220, a flag to erase all the data at once in the user area 220, and a flag for the overwrite protection of the boot area in the user area 220. For example, if the flag for the write protection is set to a disable, no writing in the user area 220 is carried out. The overwriting of the security flag is explained later.

In addition, in the other area 213 stores, for example, the information related to the accuracy of the flash memory 14, the information particular to the system of the microprocessor 10, and so on.

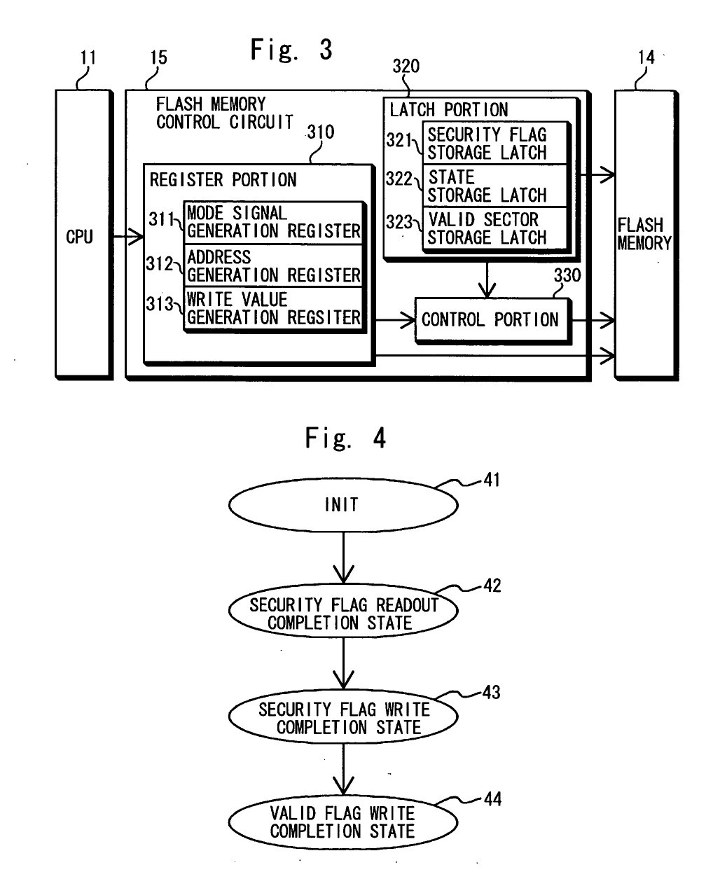

Next, the structure of the flash memory control circuit 15 according to the present embodiment is explained below with reference to FIG. 3. The flash memory control circuit 15 comprises a resistor portion 310, a latch portion 320 and a control portion 330 as shown in the figure. The resistor portion 310 is connected to the CPU 11, the control portion 330 and the flash memory 14. The control portion 330 is further connected to the latch portion 320, and the latch portion 320 is also connected to the flash memory 14.

The resistor portion 310 is a resistor which is used by the CPU 11 to instruct the operations of the flash memory control circuit 15. The resistor portion 310 comprises, for example, a mode signal generation resistor 311, an address generation resistor 312 and a new value generation resistor 313, and further comprises other various resistors.

The mode signal generation resistor 311 is a resistor which generates a mode signal for designating the writing mode to write data or the erasing mode to erase data in the flash memory 14, and outputs the mode signal to the flash memory 14. The address generation resistor 312 is a resistor which generates an address signal for designating the address to be written or the address to be erased in the flash memory 14, and outputs the address to the flash memory 14. The new value generation resistor 313 is a resistor for generating the data signal which designates new data to be written to the flash memory 14, and outputs the data to the flash memory 14.

The latch portion 320 is a latch circuit which stores the necessary information for the operation of control portion 330. The latch portion 320 comprises a security flag storage latch 321, a state storage latch 322 and a valid sector storage latch 323, and further comprises other various latches.

The security flag storage latch 321 is a latch for storing the security flag which has been read out from security flag area 212 of the flash memory 14. The state storage latch 322 is a latch for storing the state of the security flag in overwriting. The valid sector storage latch 323 is a latch for storing the information indicating which sector is valid in the system area 210 in the flash memory 14.

The control portion 330 receives the instruction from the CPU 11 via the resistor portion 310, refers to the latch portion 320 in accordance with the instruction and performs operations. The control portion 330 has a state machine to carry out the state shift explained later.

For example, once the writing mode is set by the CPU 11 in the mode signal generation resistor 311, the control portion 330 refers to the security flag storage latch 321. Then, the control portion 330 generates the mode signal to the flash memory 14 if the write protection flag is set to an enable, or does not generate the mode signal if the write protection flag is set to a disable.

Also, for example, once the address of the boot area of the flash memory 14 is set by the CPU 11 in the address generation resistor 312, the control portion 330 refers to the security flag storage latch 321. Then, the control portion 330 generates the mode signal to the flash memory 14 if the overwrite protection flag of the boot area is set to an enable, or does not generate the mode signal if the overwrite protection flag of the boot area is set to a disable. As mentioned above, by generating or not generating the mode signal, the overwrite control of the boot area is carried out.

The address designated by the address generation resistor 312 by the CPU 11 is converted into the actual physical address based on the valid area storage latch 323, and the address signal is generated and output to the flash memory 14. This enables the CPU 11 to designate the same address every time without considering whether the valid sector is the sector 0 or 1. For example, as drawn in FIG. 2B, when assigning the security flag area 212 of the sector 0 to address 0001H and reading out from or writing to the security flag area 212, upon designation of the address 0001H by the CPU 11, the control portion 330 maps to the address 0001H if the valid sector is the sector 0, or maps to the address 0801H if the valid sector is the sector 1. Then, the control portion 330 outputs the address to the flash memory 14. Similarly, when assigning the sector 1 to the address 0801H and erasing the invalid sector, upon designation of the address 0800H by the CPU 11, the control portion 330 maps to the address 0000H if the invalid sector is the sector 0, or maps to the address 0800H if the invalid sector is the sector 1. Then, the control portion 330 outputs the address to the flash memory 14.

Next, the overwrite process of the security flag according to the present embodiment is explained below with reference to FIGS. 4 to 6D.

FIG. 4 shows the state shift when overwriting the security flag. The control portion 330 performs the overwriting based on the state shift, and each state is stored in the above-mentioned state storage latch 322. In the following process, the system area 210 including the valid flag area 211 and the security flag area 212 is overwritten, and an enable or a disable for the system area 210 has been determined for each state. In addition, for example, the overwrite program for the security flag included in the base program is performed at the CPU 11, and the following process is carried out at the control portion 330 according to the commands from the CPU 11. For example, the commands to read out or write the security flag and erase the invalid sector are stated in the overwrite program for the security flag.

For example, this process is started after the overwrite program for the security flag is initiated and the security flag of the valid sector is read out. The first state is the initial state of INIT state 41. In this state, the security flag is read out from the security flag area 212 of the valid sector. The read out security flag is stored in the security flag storage latch 321. In this state, only the erasing of the invalid sector is allowed.

For example, it is possible that, when the write protection flag which has not been updated is read out, while the flag is allowed to be updated to an enable or a disable if the flag has been set to an enable, the flag is not allowed to be updated to an enable if the flag is set to a disable. This operation can also be performed such that, when writing the updated data, if the write protection flag is set to a disable by reference to the 321, only a disable is allowed to be written even if an enable is tried to be written as the updated data.

Upon completion of the readout of the security flag, the state is shifted to the security flag readout completion state 42. In this state, the updated data is written to the security flag area 212 of the invalid sector. In addition, in this state, only the writing of the security flag area 212 in the invalid sector is allowed.

Upon completion of the writing of the updated data, the state is shifted to the security flag write completion state 43. In this state, the flag indicating valid is written to the valid flag area 211 in the invalid sector. In addition, in this state, only the writing of the valid flag area 211 and the other area 213 in the invalid sector is allowed.

Upon completion of the writing of the valid flag, the state is shifted to the valid area write completion state 44. In this state, the information indicating the valid sector is stored in the valid area storage latch 323. In this state, none of the operation to overwrite to the system area 210 is allowed. As mentioned above, by updating the valid area storage latch 323, the physical address to be mapped is updated.

Then, for example, the CPU 11 designates the address of the user area 220 other than the system area 210, allowing that the state is shifted to INIT state 41. Then, in the INIT 41, the data of the invalid sector is erased. As described above, the overwrite process of the security flag is completed.

As mentioned above, by predetermining a disable or an enable of the overwriting in the system area 210 for each state, no overwrite of the security flag is allowed without the state shift, so that the reliability of the security flag is ensured. In other words, the overwriting of the security flag is allowed in the overwrite program for the security flag that states the overwriting procedure based on the sate shift of FIG. 4, while the overwriting of the security flag is prohibited in the program stating other procedures. For example, such the procedure is performed by reference to the state storage latch 322 when erasing or writing data.

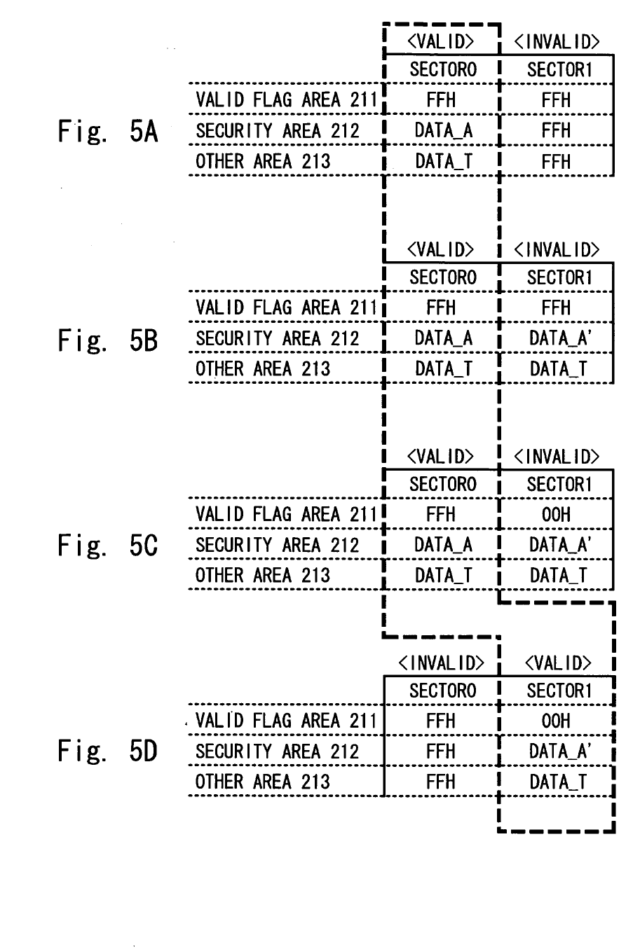

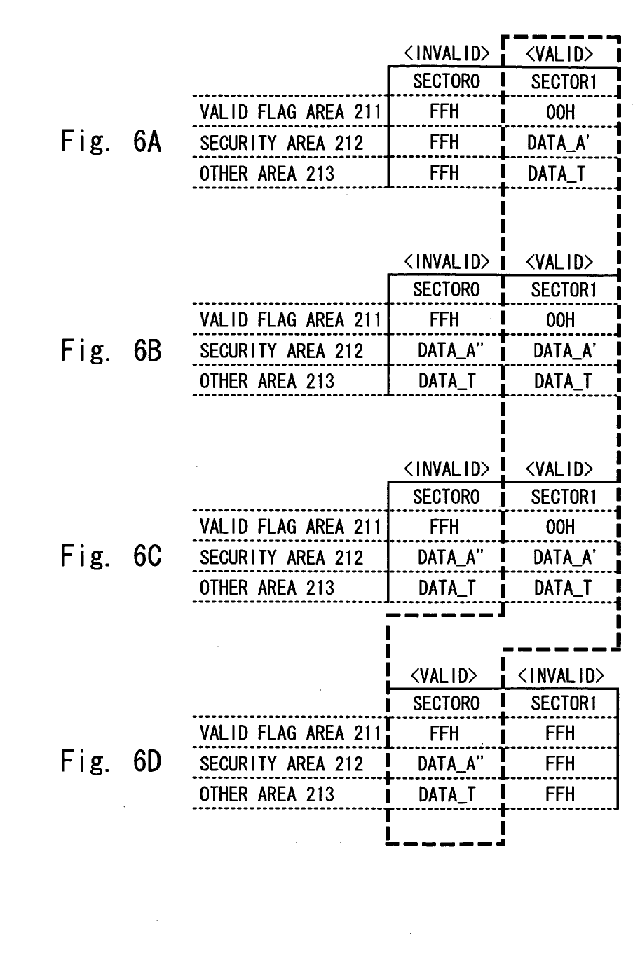

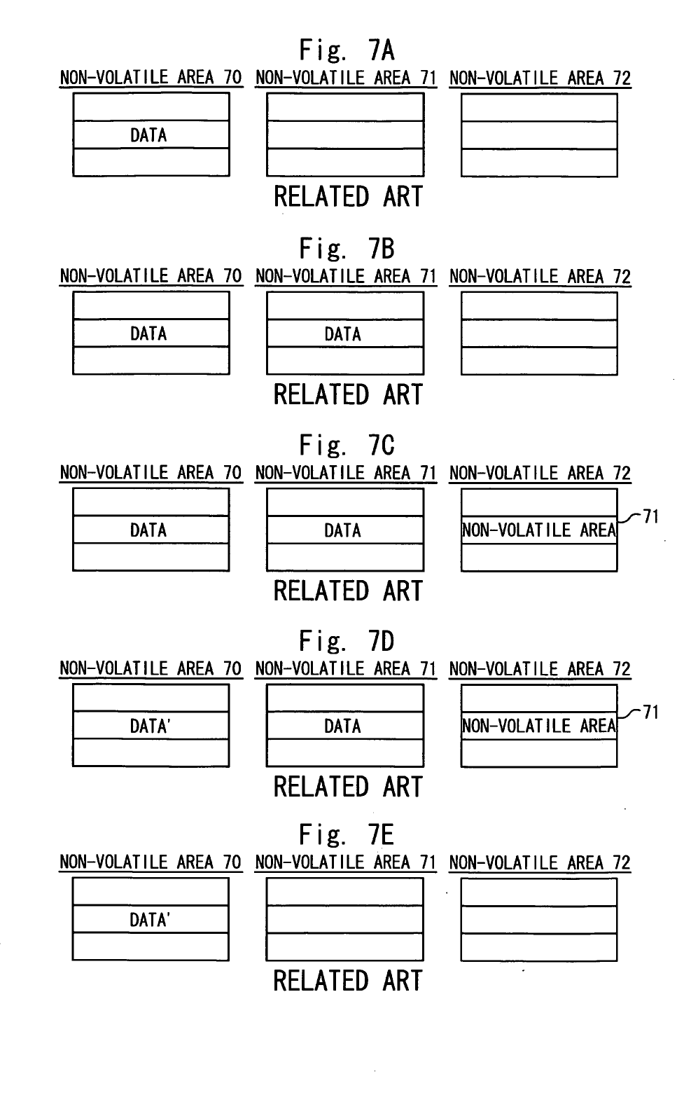

FIGS. 5A through 6D show the states of the corresponding sectors in the system area 210 when overwriting the security flag. FIGS. 5A through 6D show the states of the corresponding sectors during the security flag readout completion state 42, the security flag write completion state 43, the valid area write completion state 44 and the INIT state 41, respectively. Here, “H”, e.g., of “FFH” and “00H”, represents a hexadecimal form. While “FFH” and “00H” are exemplified as the data that are overwritten to or erased from each area, the size and value in the areas are not limited to these examples.

In this example, the sector 0 is valid if the valid flag area 211 of the sector 1 represents “FFH”, while the sector 1 is valid if the valid flag area 211 of the sector 1 represents “00H”. Otherwise, not the valid flag area 211 of the sector 1 but that of sector 0 can be used. In addition, as described above, the information representing the current valid sector is stored in the valid area storage latch 323, so that the control portion 330 typically operates by reference not to the valid flag area 211 of sector 1 but to the valid area storage latch 323. During the reboot after the power interruption, since no information remains in the valid area storage latch 323, the information on the valid sector is read out from the valid flag area 211 of the sector 1 and stored in the valid area storage latch 323. The control portion 330 can also be set to read out the valid flag area 211 of the sector 1 and identify the valid sector without using the valid area storage latch 323.

FIGS. 5A to 5D show examples in which the security flags are overwritten and the valid sectors are set to the sector 1 when the valid sectors are the sector 0. In the INIT state 41, the security flag is read out from the security flag area 212 of the valid sector, i.e., the sector 0, and the state is shifted to the security flag readout completion state 42 (FIG. 5A). In this state, the security flag “DATA_A” of the valid sector, i.e., the sector 0 is read out based on the valid area storage latch 323. It can also be set to determine the sector 0 as valid from the basis that the valid flag area 211 of the sector 1 contains “FFH”.

Next, in the security flag readout completion state 42, the updated data is written to the security flag area 212 of the invalid sector, i.e., the sector 1, the other area 213 of the sector 0 is copied to the sector 1, and the state is shifted to the security flag write completion state 43 (FIG. 5B). In this process, the updated data “DATA_A′” and the other data “DATA_T” are written.

Then, in the security flag write completion state 43, the flag indicating the valid is written to the valid flag area 211 of the invalid sector, i.e., the sector 1, and the state is shifted to the valid area write completion state 44 (FIG. 5C). In this process, “00H” is written in the valid flag area 211 of the sector 1 and information representing the validness of the sector 1 is stored in the valid area storage latch 323, which allows the control portion 330 to be operated under the condition of the sector 1 being valid. By shifting the valid flag area 211 of the sector 1 to “00H”, during the reboot after the power interruption, the valid flag area 211 of the sector 1 is referred to, and the operation under the condition of the sector 1 being valid is obtained.

Then, in the valid area write completion state 44, when the CPU 11 designates the address in the user area 220, the state is shifted to the INIT state 41 and the data in invalid sector, i.e., the sector 0, is erased (FIG. 5D). In this process, since the data is erased on a sector basis, all the areas in the sector 0 become “FFH”.

FIGS. 6A to 6D show the examples that the security flags are overwritten and the valid sectors are set to the sector 0 when the valid sectors are the sector 1. In the INIT state 41, the security flag is read out from the security flag area 212 of the valid sector, i.e., the sector 1, and the state is shifted to the security flag readout completion state 42 (FIG. 6A). In this state, the security flag “DATA_A′” of the valid sector, i.e., the sector 1, is read out based on the valid area storage latch 323. It is also possible to determine the sector 1 as valid from the basis that the valid flag area 211 of the sector 0 contains “00H”.

Next, in the security flag readout completion state 42, the updated data is written to the security flag area 212 of the invalid sector, i.e., the sector 0, the security flag area 212 of the sector 1 is copied to the sector 0, and the state is shifted to the security flag write completion state 43 (FIG. 6B). In this process, the updated data “DATA_A″” and the other data “DATA_T” are written.

Then, in the security flag write completion state 43, the flag indicating the valid is written to the valid flag area 211 of the invalid sector, i.e., the sector 0, and the state is shifted to the valid area write completion state 44 (FIG. 6C). In this process, “FFH” is written in the valid flag area 211 of the sector 0 and information representing the validness of the sector 0 is stored in the valid area storage latch 323, which allows the control portion 330 to be operated under the condition of the sector 0 being valid. Also, since the state represents “FFH” after erasing data, no data needs to be written to the valid flag area 211 of the sector 0.

Then, in the valid area write completion state 44, when CPU 11 designates the address in the user area 220, the state is shifted to the INIT state 41 and the data in the invalid sector, i.e., the sector 1, is erased (FIG. 6D). In this process, since the data is erased on a sector basis, all the areas in the sector 1 become “FFH”. By shifting the valid flag area 211 of the sector 1 to “FFH”, during the reboot after the power interruption, the valid flag area 211 of the sector 1 is referred to, and the operation under the condition of the sector 0 being valid is obtained.

Using two sectors, the method described above allows the proper operation against the power interruption that occurred when overwriting data. For example, when the microprocessor 10 is restarted after the power interruption at the state of FIG. 5B or FIG. 6B when overwriting the security flag, the operation is obtained with the proper sector information such as sector 0 in FIG. 5B or sector 1 in FIG. 6B by referring to the valid flag area 211 of the sector 1. In addition, in the subsequent operation for overwriting the security flag, by performing the brank check to see if the data of the invalid sector has been erased before the overwriting to the sector, damaged data due to the abnormal shutdown can be known, such as the sector 1 in FIG. 5B or the sector 0 in FIG. 6B.

Further, the updated data (DATA_A′ in FIGS. 5A to 5D and DATA_A″ in FIGS. 6A to 6D) is written without saving the old data (DATA_A in FIGS. 5A to 5D and DATA_A′ in FIGS. 6A to 6D), allowing the faster overwriting operation compared with the method in which data is copied and saved prior to overwritten.

Other Embodiment

In the embodiment described above, while the method of overwriting the security flag is explained, the subject for overwriting is not limited to the security flag, namely, other data, e.g., the user program or the base program, can be the subject for overwriting.

In addition, in the embodiment described above, while the method of overwriting data in the flash memory is explained, the method can be employed for other nonvolatile memories, e.g., an EPROM or an EEPROM as well as in a flash memory.

Further, in the embodiment described above, while the method of overwriting data operated on the microprocessor, the method is applicable not only to the microprocessors but also to other electrical devices, e.g., external memory devices having control circuitry for a nonvolatile memory.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

1. An electronic device, comprising:
a first and a second nonvolatile memory areas respectively having a data area for storing data and an identifying information area for storing identifying information which indicates whether the data is valid or invalid; and
an overwrite portion for overwriting data to the first and second memory areas,
wherein the overwrite portion writes new data to the data area of the second memory area if old data is stored in the data area of the first memory area, and writes the identifying information to the identifying information area of the first or second memory area, the identifying information indicating that the data area of the second memory area is valid.

2. The electronic device according to claim 1, wherein the old data and the new data are protection information which indicates an enable or a disable of overwriting in a third nonvolatile memory area.

3. The electronic device according to claim 1, wherein the first and the second memory areas are sectors of a flash memory.

4. The electronic device according to claim 2, wherein the first and the second memory areas are sectors of a flash memory.

5. A nonvolatile memory, comprising:
a first memory area, including
a first data area for storing data, and
a first identifying information area for storing identifying information which indicates whether the data is valid or invalid; and
a second memory area, including
a second data area, if old data is stored in the first data area, the second identifying information area for storing identifying information which indicates whether the data is valid or invalid,
wherein an identifying information is written to the first or second identifying information area, the identifying information indicating that the data area of the second memory area is valid.

6. A method of overwriting data in a nonvolatile memory, comprising:
writing new data to a data area of a second nonvolatile memory area if old data is stored in a data area of a first nonvolatile memory area; and
writing identifying information into a identifying information area of the first or second memory area, the identifying information indicating that the second memory area is valid.

7. The method of overwriting data in a nonvolatile memory according to claim 6, wherein the old data and the new data are protection information which indicates an enable or a disable of overwriting in a third nonvolatile memory area.

8. The method of overwriting data in a nonvolatile memory according to claim 6, wherein the first and the second memory areas are sectors of a flash memory.

9. The method of overwriting data in a nonvolatile memory according to claim 7, wherein the first and the second memory areas are sectors of a flash memory.
